(19) United States
(12) Patent Application Publication
(10) Pub. No.: US 2025/0174261 A1
(43) Pub. Date: May 29, 2025

(54) MEMORY CONTROLLER AND MEMORY CONTROL METHOD

(71) Applicant: SONY SEMICONDUCTOR SOLUTIONS CORPORATION, KANAGAWA (JP)

(72) Inventor: TAKAHIRO IKARASHI, KANAGAWA (JP)

(21) Appl. No.: 18/842,856

(22) PCT Filed: Mar. 1, 2023
(86) PCT No.: PCT/JP2023/007482

§ 371 Date: Aug. 30, 2024

(30) Foreign Application Priority Data
Mar. 8, 2022 (JP) 2022-035099

(51) Int. Cl. G11C 11/406

(52) U.S. Cl. CPC G11C 11/40615; G11C 11/40603; G11C 11/40622

(57) ABSTRACT

A memory controller according to an embodiment of the present disclosure is configured to control an access to a dynamic random access memory (DRAM). The memory controller includes an RAA counter configured to count the number of issuance of ACT commands and a command scheduler. The command scheduler is configured, in a case where a count value of the RAA counter has become greater than a first threshold value, to change tRRD, tFAW, or t32AW to a longer value, and, in a case where the count value of the RAA counter has become smaller than a second threshold value that is smaller than the first threshold value, to recover the changed value to a value before changed.

### TECHNICAL FIELD

The present disclosure relates to a memory controller and a memory control method.

### BACKGROUND ART

In recent years, it has been known, as a process of manufacturing dynamic random access memories (DRAMs) has been finely divided, that such a phenomenon called row hammer occurs that causes, in a case where accesses to a certain address have occurred continuously, a piece of data at another address physically adjacent to the address to change. Since intentionally causing row hammer to occur makes it possible to perform intentional rewriting at an address that is believed to be normally impossible to access, row hammer has been recognized as a serious security risk. An idea for coping with row hammer has been disclosed in PTL 1, for example.

### CITATION LIST

### Patent Literature

PTL 1: Japanese Unexamined Patent Application Publication (Published Japanese Translation of PCT Application) No. JP 2020-166832

### SUMMARY OF THE INVENTION

In a latest-generation DRAM standard such as low power double data rate (LPDDR) 5 or LPDDR5X, a new standard called refresh management (RFM) has been introduced to cope with row hammer. In the new standard, a rolling accumulated ACT (RAA) counter is set per bank, +1 is added to the RAA counter each time an ACT command is issued, and issuance of ACT commands is prohibited in a case where a value of the RAA counter (an RAA count value) has exceeded RFMTH. In the new standard, a refresh command (REFab) or an RFM command that has been newly introduced in the new standard is issued, and a predetermined value is subtracted from the RAA count value, making it possible to issue ACT commands.

In a case where a memory controller is designed in accordance with the new standard, it is necessary to add an RAA counter and a circuit that issues an RFM command. However, since row hammer itself only occurs in a case where row hammer is intentionally caused to occur, it is desirable to take a measure against row hammer by also utilizing an existing function, while suppressing as much as possible introduction of a new circuit. Therefore, it is desirable to provide a memory controller and a memory control method that make it possible to take a measure against row hammer by utilizing an existing function.

A memory controller according to an embodiment of the present disclosure is configured to control an access to a dynamic random access memory (DRAM). The memory controller includes: a rolling accumulated ACT (RAA) counter configured to count the number of issuance of ACT commands; and a command scheduler. The command scheduler is configured, in a case where a count value of the RAA counter has become greater than a first threshold value, to change any one of three parameters described below to a longer value, and, in a case where the count value of the RAA counter has become smaller than a second threshold value that is smaller than the first threshold value, to recover the changed value to a value before changed.
(A1) Issuance interval tRRD for ACT commands
(A2) Period of time tFAW allowing four ACT commands to be present
(A3) Period of time t32AW allowing 32 ACT commands to be present in a graphics double data rate type six synchronous dynamic random-access memory (GDDR6) standard

A memory control method according to the embodiment of the present disclosure is directed to a method for controlling an access to a DRAM. The memory control method includes two acts described below.
(B1) Changing, in a case where a count value of an RAA counter has become greater than a first threshold value, any one of three parameters described below to a longer value
(B2) Recovering, in a case where the count value of the RAA counter has become smaller than a second threshold value that is smaller than the first threshold value, the changed value to a value before changed

### Parameters to be Changed

(A1) Issuance interval tRRD for ACT commands
(A2) Period of time tFAW allowing four ACT commands to be present
(A3) Period of time t32AW allowing 32 ACT commands to be present in the graphics double data rate type six synchronous dynamic random-access memory (GDDR6) standard

In the memory controller and the memory control method according to the embodiment of the present disclosure, in a case where the count value of the RAA counter has become greater than the first threshold value, any one of the three parameters described above is changed to a longer value, and, in a case where the count value of the RAA counter has become smaller than the second threshold value that is smaller than the first threshold value, the changed value is recovered to the value before changed. As described above, changing an existing parameter suppresses an increase in the count value.

### BRIEF DESCRIPTION OF DRAWING

FIG. 1 is a diagram illustrating a functional block example of an ordinary memory controller.

FIG. 2 is a diagram illustrating an example of a situation in a case where an RAA count value changes.

FIG. 3 is a diagram illustrating a functional block example of a memory controller according to an embodiment of the present disclosure.

FIG. 4 is a diagram illustrating an example of a situation in a case where an RAA count value changes.

FIG. 5 is a diagram for describing extension of tRRD.

FIG. 6 is a diagram for describing extension of tFAW.

FIG. 7 is a diagram for describing extension of t32AW.

### MODES FOR CARRYING OUT THE INVENTION

In the following, an embodiment of the present disclosure will be described in detail with reference to the drawings. However, the embodiment described below is a mere example, and there is no intention of excluding application of various types of modifications and techniques that are not clearly expressed. It is possible to variously modify and implement the present technique (for example, by combining the embodiment with another embodiment) without departing from its scope. Furthermore, for identical or similar components illustrated in the drawings described below, identical or similar symbols are applied and indicated. The drawings are schematic, and dimensions and ratios in there do not necessarily coincide with actual dimensions and ratios. The drawings may contain differences in mutual dimensional relationships and ratios.

### 1. Issues in Latest-Generation Standards

Synchronous dynamic random access memories (synchronous DRAMs or SDRAMs) that are advantageous in terms of price, bus band, and capacity have been widely used as memory systems. Such an SDRAM is a DRAM that operates in synchronization with a clock signal, and includes a plurality of banks in many cases.

In the SDRAM having the configuration described above, a refresh command (FEFab) is inputted on a regular basis from a memory controller, and a refresh operation is performed, making it possible to hold a piece of data in a memory cell. It has been known that data-holding time is dependent on a temperature. In recent years, as a process of manufacturing SDRAMs has been finely divided, new factors that may shorten the data-holding time are regarded as issues. Specifically, such a phenomenon called row hammer has been found that causes, in a case where accesses to a certain address in an SDRAM have occurred continuously, a piece of data at another address physically adjacent to the address to change. Since intentionally causing row hammer to occur makes it possible to perform intentional rewriting at an address that is believed to be normally impossible to access, row hammer has been recognized as a serious security risk.

In an LPDDR4 standard, a new standard called target row refresh (TRR) has been introduced. The LPDDR4 standard is a DRAM standard stipulated in a join electron device engineering council (JEDEC). It is necessary, in the new standard, in a case where an accumulated number of issuance of ACT commands to a ROW address in a certain bank exceeds a threshold value designated per DRAM, a memory controller to issue a trigger for protecting a memory cell. However, it has not been easy to incorporate a function of detecting the accumulated number of issuance described above in the memory controller.

In a latest-generation DRAM standard such as LPDDR5 or LPDDR5X, a new standard called RFM has been introduced to cope with row hammer. The LPDDR5 standard and the LPDDR5X standard are DRAM standards stipulated in the JEDEC. In the new standard, an RAA counter is set per bank, +1 is added to the RAA counter each time an ACT command is issued, and issuance of ACT commands is prohibited in a case where a value of the RAA counter (an RAA count value) has exceeded RFMTH. In the new standard, a refresh command (REFab) or an RFM command that has been newly introduced in the new standard is issued, and a predetermined value is subtracted from the RAA count value, making it possible to issue ACT commands.

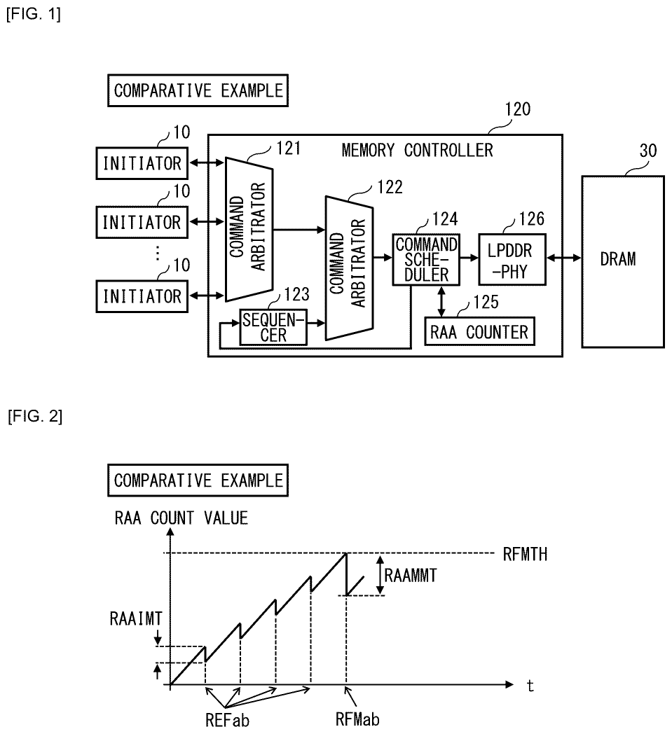

In a case where a memory controller is designed in accordance with the new standard, it is necessary to add an RAA counter and a circuit that issues an RFM command to the memory controller. FIG. 1 illustrates an example of an outline configuration of an information processing system including a memory controller 120 designed in accordance with the new standard. The information processing system includes, for example, as illustrated in FIG. 1, a plurality of initiators 10, the memory controller 120, and a DRAM 30.

The DRAM 30 is a DRAM conforming to LPDDR5 or LPDDR5X. In the DRAM 30, for example, a plurality of bank groups is specified. In each of the bank groups, for example, a plurality of banks is specified.

The plurality of initiators 10 is configured to write a piece of data into or read a piece of data from the DRAM 30 via the memory controller 120. Each of the initiators 10 is, for example, a central processing unit (CPU) or a functional block.

Each of the initiators 10 is configured to issue and output, to the memory controller 120, a memory access request for writing a piece of data into or for reading a piece of data from the DRAM 30. The memory access request includes, for example, a logical address in a virtual storage region given per each of the initiators 10, a BL length that is a length of a piece of data that should be accessed, identification information for identifying each of the initiators 10, and a transfer direction. The transfer direction referred in here indicates either a write request for writing a piece of data or a read request for reading a piece of data. Each of the initiators 10 is configured to follow a data output instruction provided from the memory controller 120 to output a piece of writing data that should be written into the DRAM 30 to the memory controller 120. Each of the initiators 10 is configured to utilize, for example, a protocol defined in an advanced microcontroller bus architecture (AMBA) (for example, an Advanced extensible Interface (AXI) protocol), and to communicate with the memory controller 120.

The memory controller 120 includes, for example, as illustrated in FIG. 1, command arbitrators 121 and 122 and a sequencer 123. The sequencer 123 is a circuit provided in accordance with an RFM standard.

The memory controller 120 is configured to communicate with each of the initiators 10 to receive a memory access request from each of the initiators 10. The memory access request is, for example, a write request or a read request. The memory controller 120 is configured to control, on the basis of the received memory access request, a write operation into the DRAM 30 or a read operation from the DRAM 30.

The memory controller 120 is configured, in a case where a write request is received from one of the initiators 10, to further receive a piece of data for writing purpose from the one of the initiators 10. The memory controller 120 is configured to issue a write command to the DRAM 30, and to transmit the piece of data received from the one of the initiators 10 to the DRAM 30. The DRAM 30 is configured to write the piece of data received from the memory controller 120 into its internal memory cell array.

The memory controller 120 is configured, in a case where a read request is received from one of the initiators 10, to issue and transmit a read command to the DRAM 30. The DRAM 30 is configured to follow the read command, to read a piece of data from the memory cell array, and to transmit the read piece of data to the memory controller 120. The memory controller 120 is configured to transmit the piece of data received from the DRAM 30 to the one of the initiators 10.

The memory controller 120 is configured to convert a logical address included in a memory access request outputted from one of the initiators 10 into a physical address corresponding to the DRAM 30. The physical address referred in here is an address indicating a bank, a row, and a column forming the DRAM 30, and includes a bank address, a row address, and a column address. As described above, as the logical address is converted into the physical address, the memory access request after converted indicates a bank address, a row address, and a column address in the DRAM 30.

The command arbitrator 121 is configured to perform arbitration on the basis of physical addresses indicated in a plurality of memory access requests acquired from the plurality of initiators 10. The command arbitrator 121 is configured to output, on the basis of a result of the arbitration, the plurality of memory access requests to the command arbitrator 122. The sequencer 123 issues an RFM request on the basis of a notification from the command scheduler 124. The sequencer 123 is configured to output the issued RFM request to the command arbitrator 122. The command arbitrator 122 is configured to perform arbitration on the basis of memory access requests acquired from the command arbitrator 121 and the sequencer 123. The command arbitrator 122 is configured to output, on the basis of a result of the arbitration, the plurality of memory access requests to the command scheduler 124.

The command arbitrator 121 is configured, for example, in a case where a memory access request is received simultaneously from each of the initiators 10, to suppress outputting of a memory access request having a bank address identical to a bank address in a memory access request outputted immediately before. That is, the command arbitrator 121 is configured, in a case where a plurality of memory access requests is received, to output a memory access request having a bank address different from a bank address in a memory access request outputted immediately before. The command arbitrator 121 is configured, in a case where a write request is to be outputted as a memory access request, to instruct outputting a piece of writing data corresponding to the memory access request to an identified one of the initiators 10 on the basis of identification information indicated in the memory access request.

The memory controller 120 further includes a command scheduler 124, an RAA counter 125, and an LPDDR-PHY (hereinafter simply referred to as a “physical layer”.) 126. The RAA counter 125 is a circuit provided in accordance with the RFM standard.

The command scheduler 124 is configured to issue a command to the DRAM 30 on the basis of a memory access request outputted from the command arbitrator 122. The memory controller 120 is configured to output a piece of writing data stored in its internal buffer to the DRAM 3 in synchronization with issuance of a write command. The memory controller 120 is configured to read, from the DRAM 30, and to store, in the internal buffer, a piece of reading data in synchronization with issuance of a read command.

The physical layer 126 is configured to output a command supplied in synchronization with an operation clock in the memory controller 120 and a piece of writing data stored in the internal buffer on the basis of a memory clock in the DRAM 30. Furthermore, the physical layer 126 is configured to store the piece of data read in synchronization with the memory clock in the DRAM 30 in the internal buffer in a synchronized manner with the operation clock in the memory controller 120.

The RAA counter 125 is configured to count the number of issuance of ACT commands in the command scheduler 124. The memory controller 120 is configured, for example, each time an ACT command is issued, to output a count signal to the RAA counter 125. The RAA counter 125 is configured, for example, each time a count signal is inputted from the memory controller 120, to add +1 to the count value (an RAA count value) of the RAA counter 125.

FIG. 2 illustrates an example of a situation in a case where an RAA count value changes. The command scheduler 124 is configured to periodically issue a refresh command (REFab). The command scheduler 124 is configured to output a notification for issuing an RFM request to the sequencer 123 on the basis of the RAA count value. The command scheduler 124 is configured, for example, in a case where the RAA count value has become greater than a predetermined threshold value (a threshold value RFMTH), to output a notification for issuing an RFM request to the sequencer 123. The sequencer 123 is configured to issue an RFM request on the basis of a notification from the command scheduler 124. The command scheduler 124 is configured to issue an RFM command (RFMab) to the DRAM 30 on the basis of an RFM request outputted from the command arbitrator 122.

The command scheduler 124 is configured, each time a refresh command (REFab) is issued, to output a first discount signal to the RAA counter 125. The RAA counter 125 is configured, for example, each time a first discount signal is inputted from the memory controller 120, to subtract a predetermined value (a subtraction value RAAIMT) from the RAA count value (see FIG. 2). The command scheduler 124 is configured, each time an RFM command (RFMab) is issued, to output a second discount signal to the RAA counter 125. The RAA counter 125 is configured, for example, each time a second discount signal is inputted from the memory controller 120, to subtract a predetermined value (a subtraction value RAAMMT) from the RAA count value (see FIG. 2).

In the comparative example, as described above, it is possible to use a refresh command (REFab) and an RFM command (RFMab) to make an RAA count value to be equal to or lower than a predetermined threshold value (the threshold value RFMTH). Thereby, occurrence of row hammer is suppressed.

By the way, row hammer itself only occurs in a case where row hammer is intentionally caused to occur. Therefore, it is desirable to take a measure against row hammer by also utilizing an existing function, while suppressing as much as possible introduction of a new circuit. Then, the inventors of the present application have come to an idea that makes it possible to take a measure against row hammer by further utilizing an existing function. The idea will now be described herein.

### 2. Embodiment

### Configuration

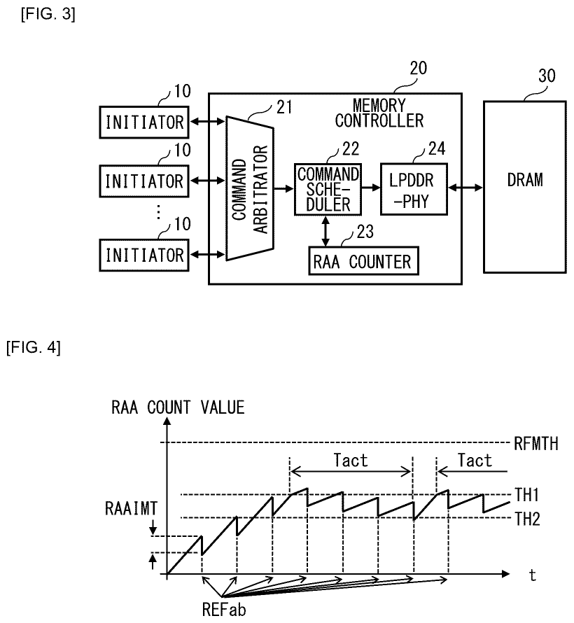

FIG. 3 illustrates an example of an outline configuration of an information processing system including a memory controller 20 according to an embodiment of the present disclosure. The information processing system includes, for example, as illustrated in FIG. 3, a plurality of initiators 10, the memory controller 20, and a DRAM 30. The initiators 10 and the DRAM 30 have configurations described above.

The memory controller 20 is configured to control an access to the DRAM 30. The memory controller 20 includes, for example, as illustrated in FIG. 3, a command arbitrator 21, a command scheduler 22, an RAA counter 23, and an LPDDR-PHY (hereinafter simply referred to as a “physical layer”.) 24.

The memory controller 20 is configured to communicate with each of the initiators 10 to receive a memory access request from each of the initiators 10. The memory access request is, for example, a write request or a read request. The memory controller 20 is configured to control, on the basis of the received memory access request, a write operation into the DRAM 30 or a read operation from the DRAM 30.

The memory controller 20 is configured, in a case where a write request is received from one of the initiators 10, to further receive a piece of data for writing purpose from the one of the initiators 10. The memory controller 20 is configured to issue a write command to the DRAM 30, and to transmit the piece of data received from the one of the initiators 10 to the DRAM 30. The DRAM 30 is configured to write the piece of data received from the memory controller 120 into its internal memory cell array.

The memory controller 20 is configured, in a case where a read request is received from one of the initiators 10, to issue and transmit a read command to the DRAM 30. The DRAM 30 is configured to follow the read command, to read a piece of data from the memory cell array, and to transmit the read piece of data to the memory controller 20. The memory controller 20 is configured to transmit the piece of data received from the DRAM 30 to the one of the initiators 10.

The memory controller 20 is configured to convert a logical address included in a memory access request outputted from one of the initiators 10 into a physical address corresponding to the DRAM 30. The physical address referred in here is an address indicating a bank, a row, and a column forming the DRAM 30, and includes a bank address, a row address, and a column address. As described above, as the logical address is converted into the physical address, the memory access request after converted indicates a bank address, a row address, and a column address in the DRAM 30.

The command arbitrator 21 is configured to perform arbitration on the basis of physical addresses indicated in a plurality of memory access requests acquired from the plurality of initiators 10. The command arbitrator 21 is configured to output, on the basis of a result of the arbitration, the plurality of memory access requests to the command scheduler 22.

The command arbitrator 21 is configured, for example, in a case where a memory access request is received simultaneously from each of the initiators 10, to suppress outputting of a memory access request having a bank address identical to a bank address in a memory access request outputted immediately before. That is, the command arbitrator 21 is configured, in a case where a plurality of memory access requests is received, to output a memory access request having a bank address different from a bank address in a memory access request outputted immediately before. The command arbitrator 21 is configured, in a case where a write request is to be outputted as a memory access request, to instruct outputting a piece of writing data corresponding to the memory access request to an identified one of the initiators 10 on the basis of identification information indicated in the memory access request.

The command scheduler 22 is configured to issue a command to the DRAM 30 on the basis of a memory access request outputted from the command arbitrator 21. The memory controller 20 is configured to output a piece of writing data stored in its internal buffer to the DRAM 3 in synchronization with issuance of a write command. The memory controller 20 is configured to read, from the DRAM 30, and to store, in the internal buffer, a piece of reading data in synchronization with issuance of a read command.

The physical layer 24 is configured to output a command supplied in synchronization with an operation clock in the memory controller 20 and a piece of writing data stored in the internal buffer on the basis of a memory clock in the DRAM 30. Furthermore, the physical layer 24 is configured to store a piece of data read in synchronization with the memory clock in the DRAM 30 in the internal buffer in a synchronized manner with the operation clock in the memory controller 20.

The RAA counter 23 is configured to count the number of issuance of ACT commands in the command scheduler 22. The command scheduler 22 is configured, for example, each time an ACT command is issued, to output a count signal to the RAA counter 23. The RAA counter 23 is configured, for example, each time a count signal is inputted from the command scheduler 22, to add +1 to the count value (the RAA count value) of the RAA counter 23.

FIG. 4 illustrates an example of a situation in a case where an RAA count value changes. The command scheduler 22 is configured to periodically issue a refresh command (REFab). The command scheduler 22 is configured to change an issuance interval tRRD for ACT commands on the basis of the RAA count value. The command scheduler 22 is configured, in a case where the RAA count value has become greater than a threshold value TH1 (a first threshold value), to change the issuance interval tRRD for ACT commands to a longer value. The command scheduler 22 is configured, in a case where the RAA count value has become smaller than a threshold value TH2 (a second threshold value) that is smaller than the threshold value TH1, to recover the changed value to the value before changed.

The command scheduler 22 is configured, each time a refresh command (REFab) is issued, to output a first discount signal to the RAA counter 23. The RAA counter 23 is configured, for example, each time a first discount signal is inputted from the command scheduler 22, to subtract a predetermined value (a subtraction value RAAIMT) from the RAA count value (see FIG. 4). The command scheduler 22 is configured, in a case where the RAA count value has become greater than the threshold value TH1, to keep the value of the issuance interval tRRD for ACT commands at the longer value than the initial value until the RAA count value becomes smaller than the threshold value TH2 (an ACT-period-suppression period Tact) (see FIG. 4). As described above, in the present embodiment, changing an existing parameter suppresses an increase in the RAA count value.

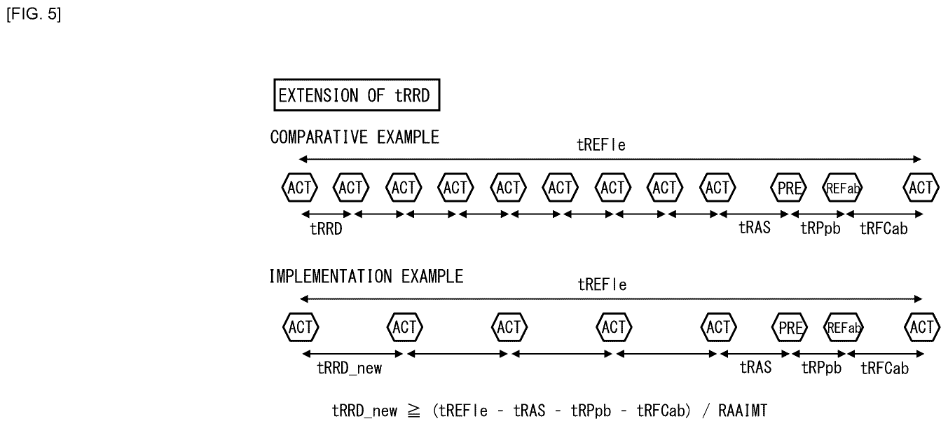

FIG. 5 is a diagram for describing extension of the issuance interval tRRD for ACT commands. In the comparative example, the command scheduler 124 keeps the issuance interval tRRD at the initial setting value. On the other hand, in an implementation example, the command scheduler 22 is configured, for example, to change the issuance interval tRRD to a value acquired with an expression described below (tRRD_new).
tRRD_new
=tREFle−tRAS−tRPpb -tRFCab)/RAAIMT
tRRD_new: Issuance interval for ACT commands after changed
tREFle: Refresh period
tRAS: Period of latency time from when a bank is opened to when the bank is closed
tRPpb: Period of latency time from when a bank is closed to when the bank is opened
tRFCab: Period of refresh cycle time

### Effects

Next, effects of the memory controller 20 according to the present embodiment will now be described herein.

In the present embodiment, in a case where the RAA count value has become greater than the threshold value TH1, the issuance interval tRRD is changed to a longer value, and, in a case where the RAA count value has become smaller than the threshold value TH2, the changed value is recovered to the value before changed. As described above, changing an existing parameter suppresses an increase in the count value. Therefore, even though no circuit that issues an RFM request is used, it is possible to take a measure against row hammer.

In the present embodiment, a refresh command is periodically issued, and, thereby, a predetermined value (the subtraction value RAAIMT) is subtracted from the RAA count value. Thereby, an increase in the RAA count value is suppressed on a regular basis. Therefore, even though no circuit that issues an RFM request is used, it is possible to take a measure against row hammer.

### 3. Modification Examples

Modification examples of the memory controller 20 according to the embodiment described above will now be described herein. In the modification examples described below, components common to the components in the embodiment described above are described with identical symbols applied.

### Modification Example A

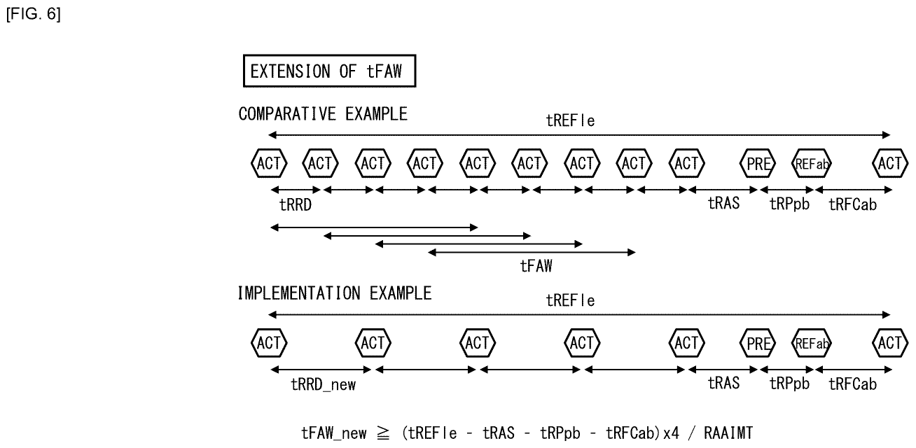

In the embodiment described above, the command scheduler 22 may be configured, in a case where the RAA count value has become greater than the threshold value TH1 (the first threshold value), for example, as illustrated in FIG. 6, to change the period of time tFAW allowing four ACT commands to be present to a longer value (tFAW_new). The command scheduler 22 may be further configured, in a case where the RAA count value has become greater than the threshold value TH1, to keep the value of the period of time tFAW at the longer value (tFAW_new) than the initial value until the RAA count value becomes smaller than the threshold value TH2 (the ACT-period-suppression period Tact). At this time, the command scheduler 22 is configured, in a case where the RAA count value has become smaller than the threshold value TH2 (the second threshold value) that is smaller than the threshold value TH1, to recover the changed value to the value before changed.

As described above, in the present modification example, changing an existing parameter suppresses an increase in the count value, similar to the embodiment described above. Therefore, even though no circuit that issues an RFM request is used, it is possible to take a measure against row hammer.

### Modification Example B

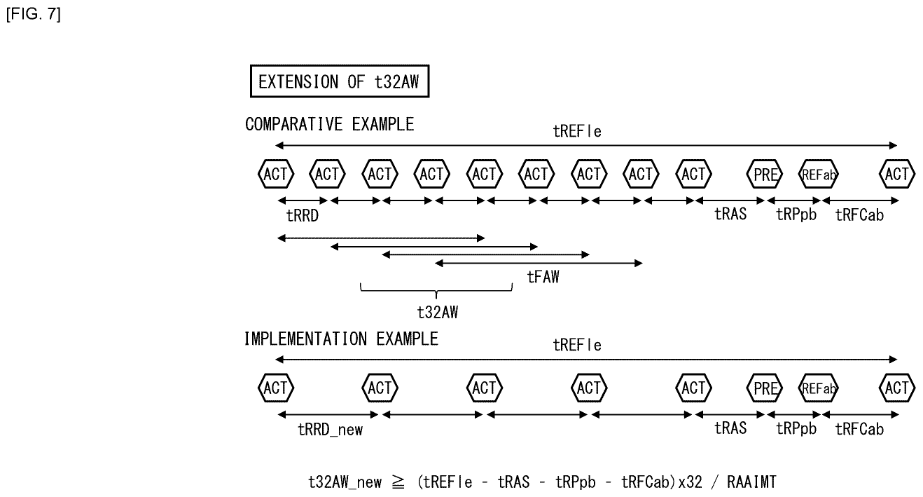

In the embodiment described above, the command scheduler 22 may be configured, in a case where the RAA count value has become greater than the threshold value TH1 (the first threshold value), for example, as illustrated in FIG. 7, to change the period of time t32AW allowing 32 ACT commands to be present in the graphics double data rate type six synchronous dynamic random-access memory (GDDR6) standard to a longer value (t32AW_new). The command scheduler 22 may be further configured, in a case where the RAA count value has become greater than the threshold value TH1, to keep the value of the period of time t32AW at the longer value (t32AW_new) than the initial value until the RAA count value becomes smaller than the threshold value TH2 (the ACT-period-suppression period Tact). At this time, the command scheduler 22 is configured, in a case where the RAA count value has become smaller than the threshold value TH2 (the second threshold value) that is smaller than the threshold value TH1, to recover the changed value to the value before changed.

As described above, in the present modification example, changing an existing parameter suppresses an increase in the count value, similar to the embodiment described above. Therefore, even though no circuit that issues an RFM request is used, it is possible to take a measure against row hammer.

### Modification Example C

In the embodiment and the modification examples described above, the command scheduler 124 may be configured, in a case where memory access requests are acquired from the plurality of initiators 10, to apply a degree of priority to each of the initiators 10. At this time, the command scheduler 124 may be configured to have the threshold values TH1 and TH2 in accordance with the degrees of priority, may be configured to use the threshold values TH1 and TH2 in accordance with an applied degree of priority, and may be configured to control the RAA count value. In such a case as described above, it is possible to take a measure against row hammer in accordance with features of the initiators 10.

### Modification Example D

In the embodiment and the modification examples described above, the command scheduler 124 may be configured, in a case where memory access requests are acquired from the initiators 10, to use the threshold values TH1 and TH2 applied to each of the initiators 10, and may be configured to control the RAA count value. In such a case as described above, it is possible to take a measure against row hammer in accordance with features of the initiators 10.

Although the present technique has been described with reference to the embodiment and the modification examples, the present disclosure is not limited to the embodiment and the modification examples described above, but may be modified in a wide variety of ways. It should be appreciated that the effects described herein are mere examples. The effects of the present disclosure are not limited to the effects described in the present specification. The present disclosure may include any other effects than those described herein.

Furthermore, for example, the present disclosure may have configurations described below.

(1)
A memory controller configured to control an access to a dynamic random access memory (DRAM), the memory controller including:
a rolling accumulated ACT (RAA) counter configured to count the number of issuance of ACT commands; and
a command scheduler configured, in a case where a count value of the RAA counter has become greater than a first threshold value, to change an issuance interval tRRD for ACT commands, a period of time tFAW allowing four ACT commands to be present, or a period of time t32AW allowing 32 ACT commands to be present in a graphics double data rate type six synchronous dynamic random-access memory (GDDR6) standard to a longer value, and, in a case where the count value of the RAA counter has become smaller than a second threshold value that is smaller than the first threshold value, to recover the changed value to a value before changed.
   (2)
The memory controller according to (1), in which the command scheduler is configured to periodically issue a refresh command, and, thereby, to subtract a predetermined value from the count value.
   (3)
A memory control method for controlling an access to a dynamic random access memory (DRAM), the memory control method including:
changing, in a case where a count value of a rolling accumulated ACT (RAA) counter configured to count the number of issuance of ACT commands has become greater than a first threshold value, an issuance interval tRRD for ACT commands, a period of time tFAW allowing four ACT commands to be present, or a period of time t32AW allowing 32 ACT commands to be present in a graphics double data rate type six synchronous dynamic random-access memory (GDDR6) standard to a longer value; and
recovering, in a case where the count value of the RAA counter has become smaller than a second threshold value that is smaller than the first threshold value, the changed value to a value before changed.
   (4)
The memory control method according to (3), further including subtracting a predetermined value from the count value by periodically issuing a refresh command.

In the memory controller and the memory control method according to the embodiment of the present disclosure, in a case where the count value of the RAA counter has become greater than the first threshold value, any one of the three parameters described above is changed to a longer value, and, in a case where the count value of the RAA counter has become smaller than the second threshold value that is smaller than the first threshold value, the changed value is recovered to the value before changed. As described above, changing an existing parameter suppresses an increase in the count value. Therefore, even though no circuit that issues an RFM command is used, it is possible to take a measure against row hammer. Note that the effects of the present disclosure are not limited to those described above, and may be any effect described herein.

This application claims the benefit of Japanese Priority Patent Application JP 2022-035099 filed with the Japan Patent Office on Mar. 8, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A memory controller configured to control an access to a dynamic random access memory (DRAM), the memory controller comprising:
a rolling accumulated ACT (RAA) counter configured to count number of issuance of ACT commands; and
a command scheduler configured, in a case where a count value of the RAA counter has become greater than a first threshold value, to change an issuance interval tRRD for ACT commands, a period of time tFAW allowing four ACT commands to be present, or a period of time t32AW allowing 32 ACT commands to be present in a graphics double data rate type six synchronous dynamic random-access memory (GDDR6) standard to a longer value, and, in a case where the count value of the RAA counter has become smaller than a second threshold value that is smaller than the first threshold value, to recover the changed value to a value before changed.

2. The memory controller according to claim 1, wherein the command scheduler is configured to periodically issue a refresh command, and, thereby, to subtract a predetermined value from the count value.

3. A memory control method for controlling an access to a dynamic random access memory (DRAM), the memory control method comprising:
changing, in a case where a count value of a rolling accumulated ACT (RAA) counter configured to count number of issuance of ACT commands has become greater than a first threshold value, an issuance interval tRRD for ACT commands, a period of time tFAW allowing four ACT commands to be present, or a period of time t32AW allowing 32 ACT commands to be present in a graphics double data rate type six synchronous dynamic random-access memory (GDDR6) standard to a longer value; and
recovering, in a case where the count value of the RAA counter has become smaller than a second threshold value that is smaller than the first threshold value, the changed value to a value before changed.

4. The memory control method according to claim 3, further comprising subtracting a predetermined value from the count value by periodically issuing a refresh command.
